(19) United States
(12) Patent Application Publication
(10) Pub. No.: US 2026/0353882 A1
(43) Pub. Date: Nov. 5, 2026

(54) DISPLAY PANEL

(71) Applicant: PlayNitride Display Co., Ltd., MiaoLi County (TW)

(72) Inventors: Yun-Li Li, MiaoLi County (TW); Kuan-Yung Liao, MiaoLi County (TW); Sheng-Yuan Sun, MiaoLi County (TW); Hoong Lien Lai, MiaoLi County (TW); Hao-Yun Lai, MiaoLi County (TW)

(73) Assignee: PlayNitride Display Co., Ltd., MiaoLi County (TW)

(21) Appl. No.: 19/322,577

(22) Filed: Sep. 8, 2025

Related U.S. Application Data
(60) Provisional application No. 63/799,776, filed on May 5, 2025.

(30) Foreign Application Priority Data
Aug. 18, 2025 (TW) 114131396

(51) Int. Cl. H10H 29/24; H10H 29/80; H10H 29/85; H10W 90/00

(52) U.S. Cl. CPC H10H 29/24; H10H 29/842; H10H 29/857; H10W 90/00

(57) ABSTRACT

Disclosed is a display panel including a circuit substrate and a plurality of display units. The circuit substrate defines a plurality of pixels. The display units are arranged on the circuit substrate to display the pixels. Each of the display units includes at least two adjacently arranged subsets. Each of the subsets includes at least three micro-light emitting chips, and the light emitting colors of the micro-light emitting chips are different from each other, wherein the micro-light emitting chips included in each display unit have at least four different light emitting colors.

### CROSS-REFERENCE TO RELATED APPLICATION

This application claims the priority benefits of U.S. provisional application Ser. No. 63/799,776, filed on May 5, 2025, and Taiwan application serial no. 114131396, filed on Aug. 18, 2025. The entirety of each of the above-mentioned patent applications is hereby incorporated by reference herein.

### BACKGROUND

### Technical Field

The present disclosure relates to a display element, and particularly relates to a display panel.

### Related Art

Display panels may be categorized into self-emissive display panels and non-self-emissive display panels. Self-emissive display panels utilize self-luminous sources such as light emitting diode (LED) chips to form pixels. Micro-LED display panels gave high color purity, high saturation, a wide color gamut and other advantages. The benefits arise from the highly consistent wavelength of the light emitted by the chips. Specifically, the full width at half maximum (FWHM) of the light spectrum is very narrow, allowing for precise control of the luminous wavelength by the emissive layer.

However, although the aforementioned characteristics of micro-light emitting diode (LED) display panels inherently achieve a broader saturation color gamut, meaning that the wavelength of light for each sub-pixel is nearly monochromatic on the CIE chromaticity diagram, it also implies that the boundaries of the displayable colors are fixed. Consequently, there is no flexibility to further expand the area of mixed colors.

### SUMMARY

The present disclosure provides a display panel that may achieve the effect of adjustable color gamut.

An embodiment of the present disclosure provides a display panel, including a circuit substrate and a plurality of display units. The circuit substrate defines a plurality of pixels. The display units are disposed on the circuit substrate to display the pixels. Each of the display units includes at least two adjacently arranged subsets. Each of the subsets includes at least three micro-light emitting chips, and the light emitting colors of the micro-light emitting chips are different from each other. The micro-light emitting chips included in each of the display units have at least four different light emitting colors.

In the display panel of the embodiment of the present disclosure, since each of the subsets includes at least three micro-light emitting chips having different light emitting colors, and since the micro-light emitting chips included in each of the display units have at least four different light emitting colors, the at least three micro light emitting chips with different light emitting colors may determine the color of a pixel, and the fourth micro light emitting chip with another different light emitting color may be utilized to adjust color coordinates of a vertex of a color gamut. Therefore, the display panel of the present disclosure may adjust the combination of micro-light emitting chips according to the color gamut corresponding to the display color of the pixel, thereby improving the user experience. For example, for display corresponding to some color gamut, micro-light emitting chips with a shorter luminous wavelength band may be turned off to achieve the effect of protecting user visual health and enhance the comfort for human eyes.

### BRIEF DESCRIPTION OF THE DRAWINGS

FIG. 1 is a partial top view of a display panel according to an embodiment of the present disclosure.

FIG. 2A shows a schematic view of a distribution range of light emitting colors emitted by a second part of a subset in FIG. 1 in a CIE 1931 chromaticity diagram.

FIG. 2B is a schematic view of a distribution range of a display unit of the present disclosure in the CIE 1931 chromaticity diagram.

FIG. 3A and FIG. 3B are partial top views of display panels according to another two embodiments of the present disclosure, respectively.

FIG. 4A is a partial top view of a display panel according to yet another embodiment of the present disclosure.

FIG. 4B is a cross-sectional schematic view of a micro-light emitting chip having two sub-chips in FIG. 4A.

FIG. 4C is a cross-sectional schematic view of another variation of the micro-light emitting chip having two sub-chips in FIG. 4A.

FIG. 5 is a partial top view of a display panel according to still another embodiment of the present disclosure.

FIG. 6 is a partial top view of a display panel according to another embodiment of the present disclosure.

### DESCRIPTION OF THE EMBODIMENTS

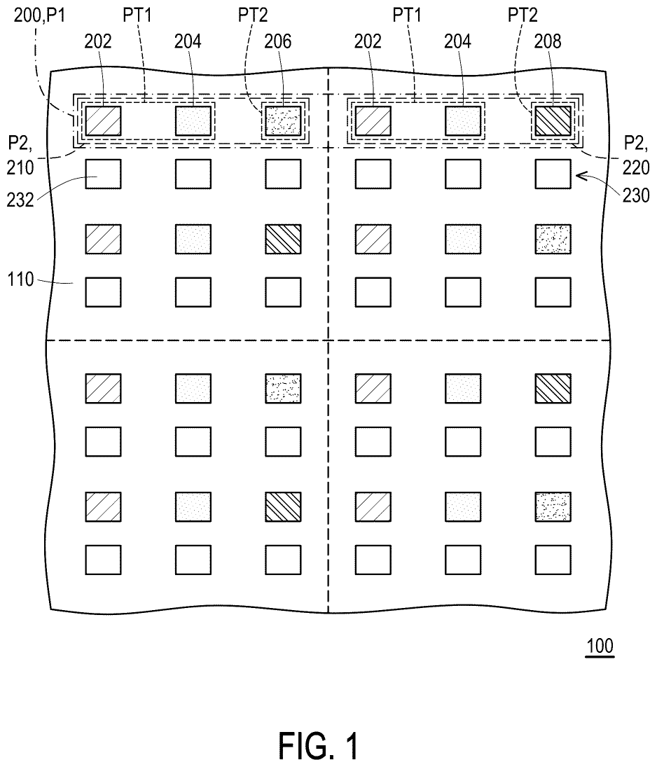

FIG. 1 is a partial top view of a display panel according to an embodiment of the present disclosure Please refer to FIG. 1, a display panel 100 of this embodiment includes a circuit substrate 110 and a plurality of display units 200. The circuit substrate 110 defines a plurality of pixels P1, and the display units 200 are disposed on the circuit substrate 110 to display the pixels P1. Each of the display units 200 includes at least two adjacently arranged subsets (in this embodiment, two adjacently arranged subsets 210 and 220 are taken as examples). Each of the subsets 210 and 220 includes at least three micro-light emitting chips, and the light emitting colors of the micro-light emitting chips are different from each other. In this embodiment, the subset 210 includes micro-light emitting chips 202, 204, and 206, while the subset 220 includes micro-light emitting chips 202, 204, and 208. The light emitting colors of the micro-light emitting chips 202, 204, 206, and 208 are different from each other. That is to say, the micro-light emitting chips included in each of the display units 200 have at least four different light emitting colors. In an embodiment, the light emitting colors of the micro-light emitting chips 202, 204, 206, and 208 are, for example, red, green, blue, and cyan, respectively.

Taking one of the display modes of this embodiment as an example, each of the display units 200 correspondingly displays one of the pixels P1, and each of the subsets 210 and 220 of each of the display units 200 is categorized into a first part PT1 and a second part PT2. The first part PT1 includes the micro-light emitting chips 202 and 204 having the same light emitting color and respectively disposed in each of the subsets 210 and 220. That is to say, the micro-light emitting chips 202 and 204 of the first part PT1 have the same color as the micro-light emitting chips 202 and 204 of the second part PT2.

The second part PT2 includes micro-light emitting chips 206 and 208 disposed only in one of the subsets 210 or 220. That is to say, the micro-light emitting chip 206 is disposed only on the subset 210; while the micro-light emitting chip 208 is disposed only on the subset 220. Since the light emitting colors of the micro-light emitting chip 206 and the micro-light emitting chip 208 are different from each other, the light emitting color of the second part PT2 on the subset 210 is different from the light emitting color of the second part PT2 on the subset 220.

In an embodiment, when the display unit 200 displays the corresponding pixel P1, the second part PT2 of one of the subsets 210 and 220 may be turned off according to the color currently corresponding to the pixel P1. For example, the first parts PT1 in both the subset 210 and the subset 220 are turned on, enabling the micro-light emitting chips 202 and 204 to generate red light and green light. Under the circumstances, the micro-light emitting chip 206 of the subset 210 is turned on to emit blue light, whereas the micro-light emitting chip 208 of the subset 220 is turned off. In this state, the first part PT1 and second part PT2 of the display unit 200 become a combination of red light, green light, and blue light. Alternatively, the micro-light emitting chip 206 of the subset 210 may be turned off, whereas the micro-light emitting chip 208 of the subset 220 is turned on. In this state, the first part PT1 and the second part PT2 become a combination of red light, green light, and cyan light. Therefore, according to different colors correspondingly displayed by the pixel P1 (for example, coordinate position (x, y) in a CIE 1931 chromaticity diagram), the display unit 200 may achieve color gamut switching by controlling the micro-light emitting chip 206 to emit light or the micro-light emitting chip 208 to emit light. Or, furthermore, the display unit 200 may move the coordinates (x, y) of mixed light formed by combining blue light and cyan light in the CIE 1931 chromaticity diagram by adjusting a luminous intensity ratio of the micro-light emitting chip 206 and the micro-light emitting chip 208, thereby achieving the effect of expanding a mixable color region.

In an embodiment, when the second part PT2 of one of the subsets (for example, the subset 210) is turned off (for example, when the micro-light emitting chip 206 is turned off), a current density of the micro-light emitting chip (for example, the micro-light emitting chip 208) of the second part PT2 of another of the subsets (for example, subset 220) may increase accordingly. Similarly, when the micro-light emitting chip 208 is turned off, the current density of the micro-light emitting chip 206 may increase accordingly. In detail, the display unit 200 may simultaneously turn on two micro-light emitting chips 202 and two micro-light emitting chips 204 to emit red light and green light respectively. Therefore, when selecting only one of the micro-light emitting chips 206 and 208 to emit light, increasing the current density thereof not only helps achieve a good balance between the light intensity of blue light (or cyan light) and the light intensities of red light and green light, but also enables an operating current of the micro-light emitting chip 206 or 208 to correspond to a higher external quantum efficiency (EQE).

As shown in FIG. 1, all of the micro-light emitting chips 206 and 208 of the second parts PT2 are alternately arranged on the circuit substrate 110 with the display units 200. Further to the aforementioned description, since there is a high possibility that adjacent pixels display similar light emitting colors in the same frame (i.e., being determined as the same color gamut), the second parts PT2 of the display units 200 may simultaneously turn on the micro-light emitting chip 206 and turn off the micro-light emitting chip 208. By alternately arranging the micro-light emitting chips 206 and 208 of each of the second parts PT2, it is possible to prevent viewers from seeing dark lines (for example, the plurality of turned-off micro-light emitting chips 208), the dark lines would affect the viewing experience. In an embodiment, the spacing between the micro-light emitting chips 202, 204, 206, and 208 is within 5 micrometers, thus achieving a good light mixing effect and meeting resolution requirements.

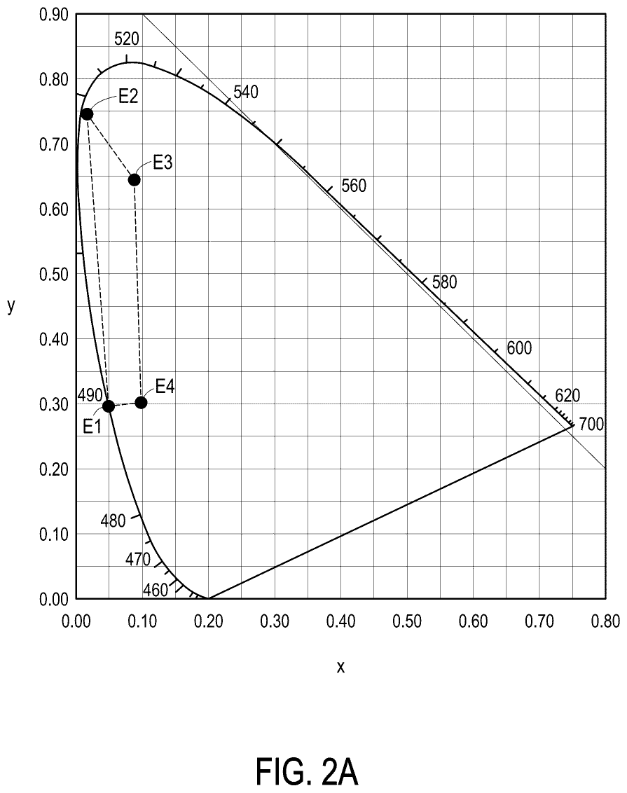

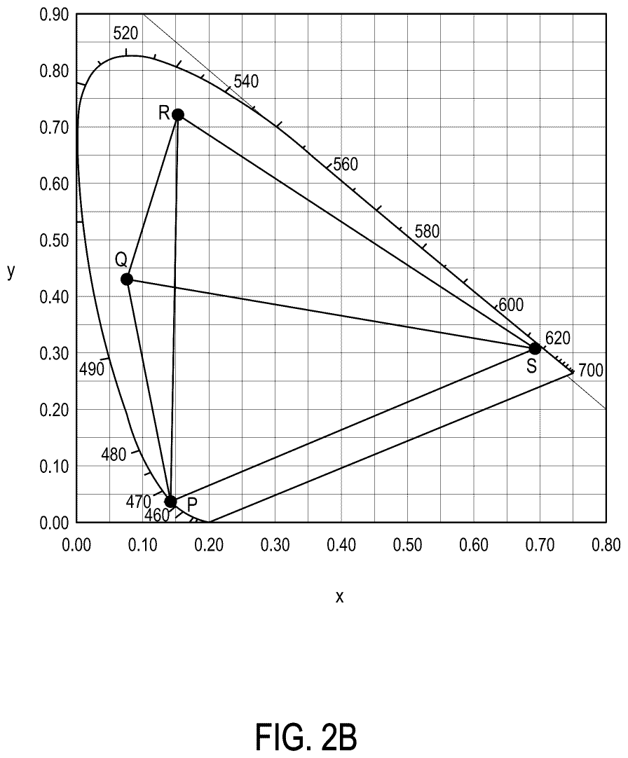

In an embodiment, the micro-light emitting chip 206 or 208 included in the second part PT2 corresponding to cyan light has its light emitting color with coordinates (x, y) in the CIE 1931 chromaticity diagram located within a region enclosed by (0.0481, 0.2953), (0.0169, 0.7460), (0.0886, 0.6449), and (0.0989, 0.3018), that is, located within a region enclosed by point E1, point E2, point E3, and point E4, as shown in FIG. 2A. The parameter values corresponding to the point E1, the point E2, the point E3, and the point E4 are shown in Table 1 below:

TABLE 1

| | Wavelength | | | |
|---|---|---|---|---|
| Point | (nm) | Color purity | CIE x | CIE y |
| E1 | 490 | 0.99 | 0.0481 | 0.2953 |
| E2 | 510 | 0.99 | 0.0169 | 0.7460 |
| E3 | 510 | 0.75 | 0.0886 | 0.6449 |
| E4 | 490 | 0.80 | 0.0989 | 0.3018 |

In another embodiment, each of the subsets 210 and 220 may respectively correspondingly display one pixel. That is, the subsets 210 and 220 may respectively serve as two pixels P2. Here, selecting the mode of using the entire display unit 200 as one pixel P1, or adopting the mode of using the subsets 210 and 220 respectively to correspondingly display the two pixels P2 may be switched by an integrated circuit on the circuit substrate 110. When the micro-light emitting chips 206 and 208 are arranged in an alternating manner, since the light emitted by the two adjacent pixels P2 will mix again before entering human eyes, it is possible to avoid that viewers perceive color differences between different columns or different rows, thereby eliminating color accuracy deviation problems caused by combinations of different light emitting color of the two adjacent pixels P2. Based on this, the display panel 100 may obtain a wider and more saturated color gamut.

In this embodiment, the display panel 100 further includes a backup line 230, which is disposed on the circuit substrate 110, and electrically connected to each of the subsets 210 and 220 of each of the display units 200. Within each of the display units 200, the backup line 230 has a plurality of bonding regions 232 corresponding to the number of the micro-light emitting chips 202, 204, 206, and 208 of each of the subsets, and the bonding regions 232 are respectively connected in parallel with the lines of the micro-light emitting chips 202, 204, 206, and 208.

Specifically, under normal circumstances, no micro-light emitting chips are disposed on the bonding regions 232. However, when the micro-light emitting chips 202, 204, 206, and 208 are damaged or defective, backup micro-light emitting chips may be disposed on the bonding regions 232 corresponding to the damaged or defective micro-light emitting chips 202, 204, 206, or 208, and electrically connected to conductive pads in the bonding regions 232, so as to be electrically connected to the backup line 230. In this way, the display panel 100 will not be affected by damaged or defective micro-light emitting chips 202, 204, 206, or 208, so that the pixel P1 or the pixel P2 is able to emit light normally.

In an embodiment, in at least one of the subsets 210 and 220, the micro-light emitting chips 202 and 204 included in the first part PT1 and having the same light emitting color respectively have a central wavelength, and a difference between any two central wavelengths ranges from 2 nanometers (nm) to 20 nm. That is, chips of the same light emitting color in different pixels P1 and P2 may have luminous wavelength differences. For example, a light emitting color of the micro-light emitting chip 202 is red, with a wavelength between approximately 610 nm to approximately 66 nm, for example, may be 620±10 nm. A light emitting color of the micro-light emitting chip 204 is green, with a wavelength between approximately 515 nm to approximately 56 nm, for example, may be 530±5 nm. A light emitting color of the micro-light emitting chip 208 is cyan, with a wavelength between approximately 480 nm to approximately 510 nm, for example, may be 500±10 nm. A light emitting color of the micro-light emitting chip 206 is blue, with a wavelength between approximately 450 nm to approximately 475 nm, for example, may be 455±5 nm.

Refer to FIG. 2B, to enhance the comfort of using the display device and reduce potential harm to eyes from blue light, the display unit 200 may further include an eye protection mode. By controlling the light emitting states of the micro-light emitting chip 206 (blue light) and the micro-light emitting chip 208 (cyan light), it is possible to achieve the purpose of inhibiting high-energy blue light output. Specifically, when the display unit 200 operates in the eye protection mode, the light emitting method of the second part PT2 corresponding to the pixel P1 may be adjusted according to preset conditions. For example, by activating the micro-light emitting chip 208 to generate the cyan light with a relatively low-energy to replace part or all of the blue light, it is possible to reduce a blue-light ingredient output to achieve the eye protection effect.

In FIG. 2B, positions of points P, Q, R and S respectively correspond to chromaticity coordinates of the blue light, the cyan light, the green light, and the red light. Points P-Q-R and points Q-R-S constitute two different groups of operable color gamut ranges, but are not limited thereto. The display unit 200 may dynamically switch between different color gamut ranges according to usage scenarios (such as high dynamic range (HDR) mode, eye protection mode, standard mode) or external sensor information (such as ambient light color temperature and intensity). For example, when the system determines that the user is in a nighttime reading environment, a control module may automatically select the Q-R-S color gamut range, so that the entire display color gamut in a warm color and low blue light region. Furthermore, the settings for the coordinates (x, y) of the mixed light in the CIE 1931 chromaticity diagram may be actively adjusted through digital control circuits and automatic adjustment algorithms. That is, the display panel 100 may automatically adapt to the aforementioned usage scenarios or modify original digital signals of pixels according to user-defined modes, so that output signals of respective pixels are mapped to another modified coordinate (for example, located in the warm color Q-R-S color gamut range), thereby achieving the effects of color temperature reduction and visual comfort enhancement.

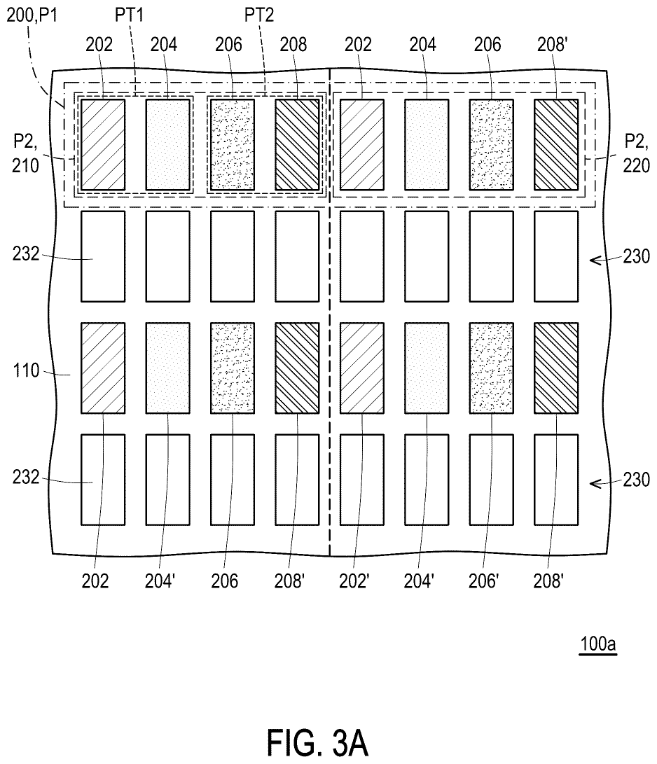

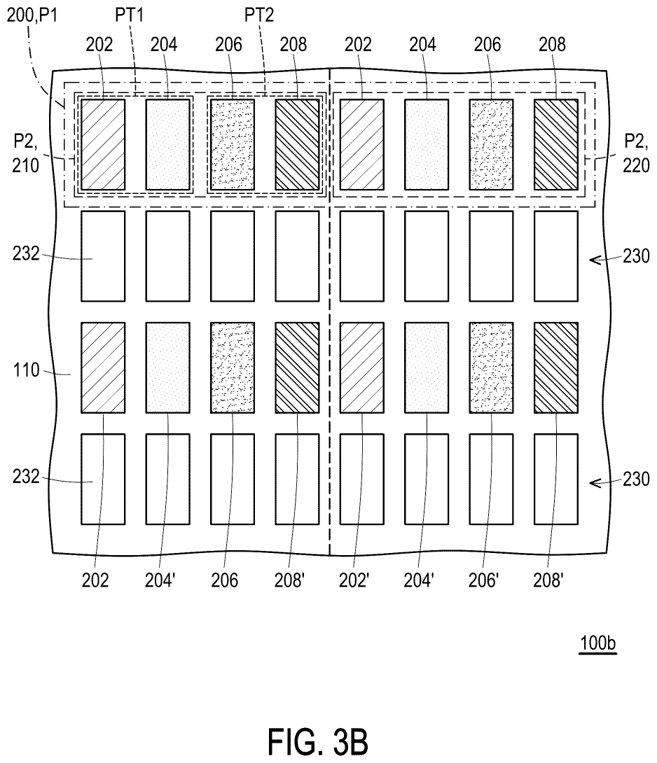

FIG. 3A and FIG. 3B are partial top views of display panels according to another two embodiments of the present disclosure, respectively. Please refer to FIG. 3A and FIG. 3B, a display panel 100a of FIG. 3A and a display panel 100b of FIG. 3B are similar to the display panel 100 of FIG. 1, and their main differences are as described below. In the display panels 100a and 100b of FIG. 3A and FIG. 3B, each of the subsets 210 and 220 includes micro-light emitting chips 202 (or 202′), 204 (or 204′), 206 (or 206′) and 208 (or 208′) having four different light emitting colors. Furthermore, in different pixels P2 or in different subsets 210 and 220, the micro-light emitting chips of the same color may have the same luminous wavelength (for example, all being micro-light emitting chips 202, 204, 206, 208), or their luminous wavelengths have differences within a range of 2 nm to 20 nm, for example, the luminous wavelengths between the micro-light emitting chips 202 and 202′, between the micro-light emitting chips 204 and 204′, between the micro-light emitting chips 206 and 206′, and between the micro-light emitting chips 208 and 208′ have differences within a range of 2 nm to 20 nm. Furthermore, in this embodiment, according to the color coordinate point of the output color, it is possible to determine the combination of the adopted light emitting chips 202 (or 202′), 204 (or 204′), 206 (or 206′) and 208 (or 208′) to be adopted, for example, using the light emitting chips 202 (or 202′), 204 (or 204′) and 206 (or 206′) to emit light, or using the light emitting chips 202 (or 202′), 204 (or 204′) and 208 (or 208′) to emit light.

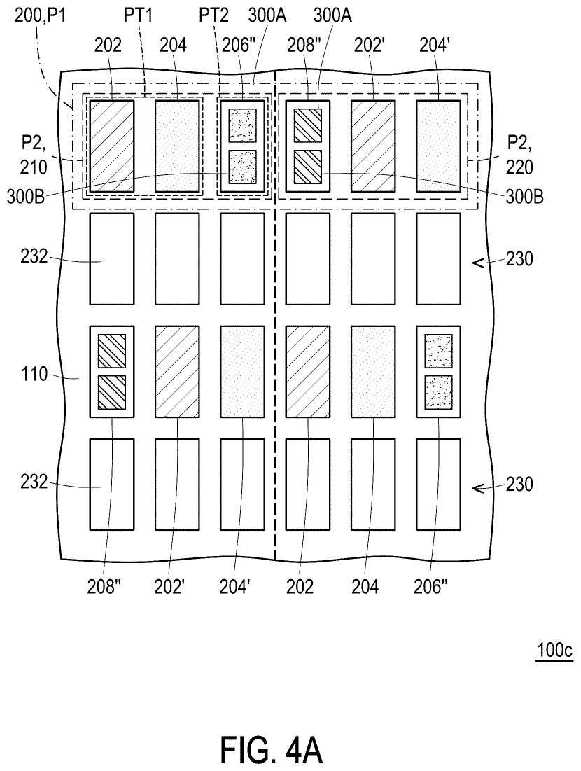

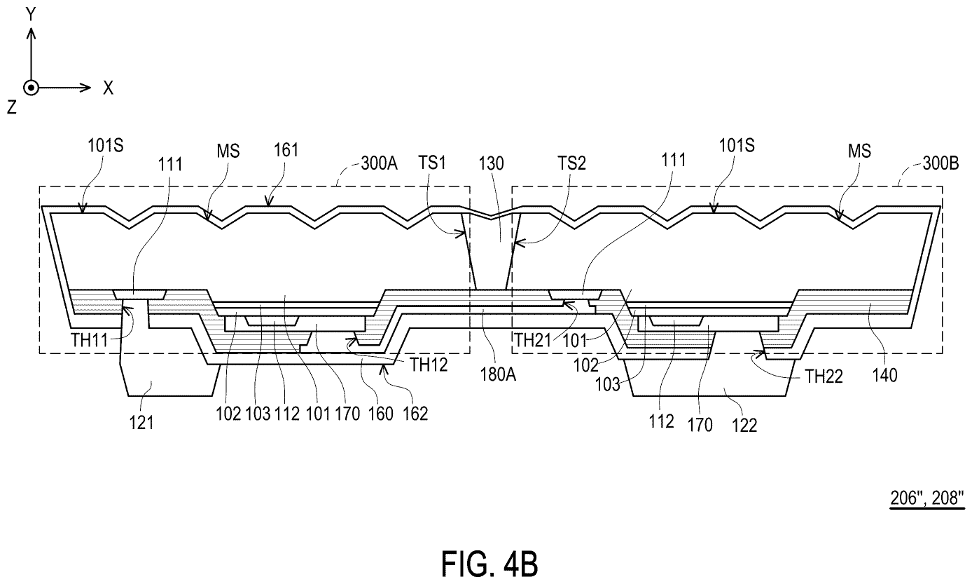

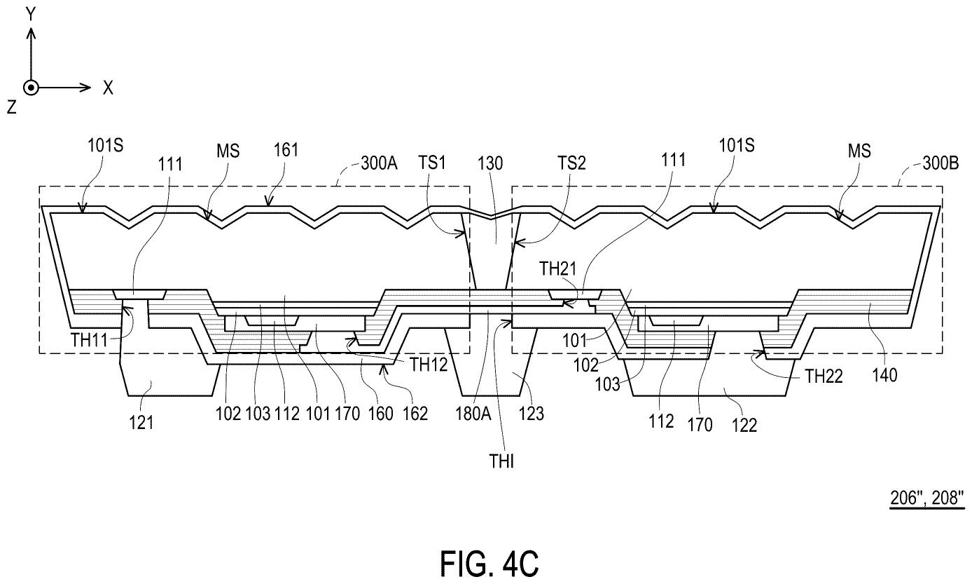

FIG. 4A is a partial top view of a display panel according to yet another embodiment of the present disclosure, and FIG. 4B is a cross-sectional view of the micro-light emitting chip having two sub-chips in FIG. 4A. Please refer to FIG. 4A and FIG. 4B, a display panel 100c of this embodiment is similar to the display panel 100 of FIG. 1, and the main differences between the two are as described below. In the display panel 100c of this embodiment, micro-light emitting chips 206″ and 208″ included in at least one second part PT2 include two sub-chips (such as first sub-chip 300A and second sub-chip 300B), a first electrode 121, a second electrode 122, an insulating structure 130, a conductive element 180A and a protection unit 160. The first sub-chip 300A and the second sub-chip 300B are, for example, micro light emitting diodes (micro LED), micro laser diodes, or light emitting diodes of other sizes, and the present disclosure is not limited thereto. Preferably, this embodiment adopts micro light emitting diodes.

On the other hand, the two sub-chips of either the micro-light emitting chip 206″ or 208″ have the same light emitting color, for example, the first sub-chip 300A and the second sub-chip 300B of the micro-light emitting chip 206″ are both blue light micro light emitting diodes, while the first sub-chip 300A and the second sub-chip 300B of the micro-light emitting chip 208″ are both cyan light micro light emitting diodes. On the other hand, the micro-light emitting chips 206″ and 208″ of this embodiment are flip-chip type micro light emitting diodes. For example, through arranging the first electrode 121 and the second electrode 122 located on the same side of an epitaxial structure of the micro-light emitting chips 206″ and 208″ to be aligned with corresponding pads on the pixel circuit, and to be bonded to each other after mass transfer, it is possible to achieve electrical connection between the micro-light emitting chips 206″ and 208″ and the pixel circuit, but the present disclosure is not limited thereto.

The first sub-chip 300A and the second sub-chip 300B each include a first semiconductor layer 101, a second semiconductor layer 102, and a light emitting layer 103 sequentially and epitaxially grown in a direction Y. One of the first semiconductor layer 101 and the second semiconductor layer 102 is an N-type semiconductor layer, and the other of the first semiconductor layer 101 and the second semiconductor layer 102 is a P-type semiconductor layer.

The first electrode 121 is electrically connected to the first semiconductor layer 101 of the first sub-chip 300A via a through hole TH11, and the second electrode 122 is electrically connected to the second semiconductor layer 102 of the second sub-chip 300B via a through hole TH22. In addition, a conductive element 180A electrically connects the two sub-chips in series. In this embodiment, the conductive element 180A is electrically connected to the first sub-chip 300A and the second sub-chip 300B, so that the first sub-chip 300A and the second sub-chip 300B are connected in series with each other. For example, the conductive element 180A may be extended in a direction X and be disposed on the same side as the first sub-chip 300A and the second sub-chip 300B. Both ends of the conductive element 180A may be electrically connected to the second semiconductor layer 102 of the first sub-chip 300A and the first semiconductor layer 101 of the second sub-chip 300B respectively. The conductive element 180A may be a metal material or a transparent conductive material.

Accordingly, when the micro-light emitting chips 206″ and 208″ are enabled, the first electrode 121 may be selectively provided with a high potential, while the second electrode 122 may be selectively provided with a low potential or a ground potential. Due to a potential difference generated between the first electrode 121 and the second electrode 122, current may flow from the first electrode 121 sequentially through the first semiconductor layer 101, the light emitting layer 103, and the second semiconductor layer 102 of the first sub-chip 300A to the conductive element 180A, and then transmitted to the first semiconductor layer 101, the light emitting layer 103, the second semiconductor layer 102, and the second electrode 122 of the second sub-chip 300B, so that the first sub-chip 300A and the second sub-chip 300B both are able to emit light.

Through the above configuration, the series-connected structure of the micro-light emitting chips 206″ and 208″ may easily adjusts the number of respective sub-chips to adjust a voltage division of the respective sub-chips, so that the respective sub-chips may be provided with a corresponding operating voltage (for example, an operating voltage of blue light micro light-emitting diodes ranges from 3.0 volts to 3.4 volts).

In addition, the insulating structure 130 is disposed between the two sub-chips to make the two sub-chips electrically insulated from each other at the insulating structure 130. In this embodiment, the insulating structure 130 is disposed between the first sub-chip 300A and the second sub-chip 300B, and makes the first sub-chip 300A and the second sub-chip 300B to be electrically insulated from each other at the insulating structure 130. The insulating structure 130 may be connected between the first semiconductor layers 101 of the first sub-chip 300A and the second sub-chip 300B and have a first contact surface TS1 and a second contact surface TS2, respectively. That is, portions of the two sub-chips respectively adjacent to the insulating structure 130 are single electrical semiconductors (for example, the first contact surface TS1 contacts the first semiconductor layer 101 of the first sub-chip 300A without contacting the second semiconductor layer 102 of the first sub-chip 300A).

In addition, the protection unit 160 may be an insulating layer composed of an insulating material. Specifically, the protection unit 160 in this embodiment is disposed on outer surfaces of the first sub-chip 300A, the second sub-chip 300B and the insulating structure 130, and has a first surface 161 and a second surface 162 opposite to each other in the direction Y, with the first sub-chip 300A, the second sub-chip 300B and the insulating structure 130 located between the first surface 161 and the second surface 162. The first surface 161 and the second surface 162 of the protection unit 160 may partially cover or completely cover the outer surfaces or upper surfaces 101S of the first sub-chip 300A, the second sub-chip 300B and the insulating structure 130.

In addition, the first sub-chip 300A and the second sub-chip 300B in this embodiment may each further include a first contact layer 111 and a second contact layer 112. The first contact layer 111 is disposed between the first semiconductor layer 101 and the first electrode 121, and the second contact layer 112 is disposed on the second semiconductor layer 102.

On the other hand, the micro-light emitting chips 206″ and 208″ may further include a Bragg reflector layer 140. The Bragg reflector layer 140 may be extended in the direction X and simultaneously cover the same side of the first sub-chip 300A and the second sub-chip 300B. Moreover, in the direction Y, the Bragg reflector layer 140 is disposed between the first sub-chip 300A and the first electrode 121, and disposed between the second sub-chip 300B and the second electrode 122. In this embodiment, the X direction is substantially perpendicular to the Y direction, and both the X direction and the Y direction are substantially perpendicular to a Z direction. The Bragg reflector layer 140 may function as an insulator and a light beam reflector. The aforementioned conductive element 180A may be electrically connected to the second semiconductor layer 102 of the first sub-chip 300A and the first semiconductor layer 101 of the second sub-chip 300B respectively via a through hole TH12 and a through hole TH21 that passes through the Bragg reflector layer 140. The conductive element 180A may be disposed between the Bragg reflector layer 140 formed of an inorganic material and the protection unit 160 to avoid breakage.

On the other hand, the micro-light emitting chips 206″ and 208″ in this embodiment may further include a transparent conductive layer 170. The transparent conductive layer 170 may serve as a current spreading layer, covering the second contact layer 112 of the first sub-chip 300A and disposed between the second semiconductor layer 102 and the conductive element 180A. The transparent conductive layer 170 may also cover the second contact layer 112 of the second sub-chip 300B and may be disposed between the second semiconductor layer 102 and the second electrode 122.

The structure where the micro-light emitting chips 206″ and 208″ include two sub-chips may be applied to a configuration where a single display unit 200 serves as the pixel P1, or applied to a configuration where a single subset 210 or 220 serves as the pixel P2.

The structure of the micro-light emitting chips 206″ and 208″ may also be the structure of FIG. 4C. Compared to the structure of FIG. 4B, the structure of FIG. 4C has an additional intermediate electrode 123, which is electrically connected to the conductive element 180A and the circuit substrate 110. The intermediate electrode 123 may have the same material as the first electrode 121 or the second electrode 122. The number of the intermediate electrodes 123 may be the same as the number of corresponding conductive elements 180A, and electrically connected to the conductive element 180A through a through hole THI passing through the protection unit 160. The intermediate electrode 123 may be applied with a corresponding voltage to regulate the current of respective sub-chips in the micro-light emitting chips 206″ and 208″ to adjust the brightness or switching of the first sub-chip 300A and the second sub-chip 300B. It is worth mentioning that in the cross-sectional view of FIG. 4C, the first electrode 121, the second electrode 122 and the intermediate electrode 123 are located on the same cross-section, but the present disclosure is not limited thereto. In other embodiments not shown, the first electrode 121, the second electrode 122 and the intermediate electrode 123 may also not be located on the same cross-section.

In this embodiment, each of the two sub-chips of the same color (such as the first sub-chip 300A and the second sub-chip 300B) has a central wavelength, and the difference between the two central wavelengths ranges from 2 nm to 20 nm. By combining with adjustment of a potential value of the intermediate electrode 123, the brightness of the first sub-chip 300A and the second sub-chip 300B may be controlled respectively to achieve fine color tuning. Due to the first sub-chip 300A and the second sub-chip 300B having slightly different central wavelengths, their brightness variations will affect a composite spectrum of the micro-light emitting chips 206″ and 208″. By adjusting a contribution ratio thereof in a spectrum, for example, increasing a potential difference between the first electrode 121 and the intermediate electrode 123, the central wavelength of the composite spectrum may move toward the central wavelength of the first sub-chip 300A. In an embodiment, the light emitting colors of the first sub-chip 300A and the second sub-chip 300B may correspond to different coordinates within the color gamut of FIG. 2A (for example, within the region enclosed by point E1, point E2, point E3 and point E4). In this way, it is possible to obtain a more significant color gamut expansion effect by only relying on the second part PT2 of the subset 210 or 220. Here, the intermediate electrode 123 is disposed to fix a potential between the first sub-chip 300A and the second sub-chip 300B to control a potential difference between the positive and negative electrodes of the two sub-chips, thereby controlling the brightness thereof to achieve coordinate movement on the CIE 1931 chromaticity diagram.

In addition, since the micro-light emitting chips 206″ and 208″ include sub-chips with smaller light emitting areas, under the same input current, compared to chips with larger areas, the micro-light emitting chips 206″ and 208″ have a higher current density, enabling the micro-light emitting chips 206″ and 208″ to operate in a range with a better external quantum efficiency. Specifically, in a mode where a single display unit 200 serves as one pixel P1, one of the micro-light emitting chips 206″ and 208″ may be turned off based on color coordinate points, and the current density of the other of the micro-light emitting chips 206″ and 208″ may be increased. In practical applications, because the display panel 100 has a higher power under white light applications, where blue light only accounts for 10% of the output ratio, choosing the mode of using the micro-light emitting chips 202 (or 202′), 204 (or 204′) and 208″ to emit light (i.e., combination of red light, green light and cyan light) makes it possible to avoid the problems of thermal degradation and reduced external quantum efficiency of the micro-light emitting chip 208″. Furthermore, adopting the design of making the first sub-chip 300A and the second sub-chip 300B of the micro-light emitting chip 208″ to emit cyan light may significantly reduce the degree of screen yellowing under the eye protection mode (i.e., turning off the micro-light emitting chip 206″ that emits blue light). Refer to FIG. 2A again, when the pixels P1 and P2 are disposed with the plurality of sub-chips described above, their maximum coverage range on the CIE 1931 chromaticity diagram is still mainly determined by the micro-light emitting chip 206″. However, as the distance between the first sub-chip 300A and the second sub-chip 300B of the micro-light emitting chip 208″ increases within a region enclosed by the points E1 to E4, the coverage range of the micro-light emitting chip 208″ will significantly increase. That is, by utilizing the characteristic that chromaticity boundary changes corresponding to cyan light wavelength variations are relatively smooth, the wavelength difference between the first sub-chip 300A and the second sub-chip 300B may cover a higher proportion of color rendering combinations, so that most colors (originally mixed with red light, green light and blue light) may be replaced by red light, green light and cyan light. Moreover, under the application of FIG. 2B, when adopting the design where the first sub-chip 300A and the second sub-chip 300B have different wavelengths (i.e., the color coordinate position of the point Q is two or more), the coordinate points that the digital control circuit can map will be significantly expanded, balancing the comfort for human eyes as well as a color gamut breadth of a display screen. In addition, in a mode where a single subset 210 or 220 serves as one pixel P2, it can also be applied to the aforementioned color coordinate point switching. For example, the intermediate electrode 123 and the first electrode 121 are made equipotential based on the color coordinate points of the light emitting color. In this state, in the micro-light emitting chip 206″, the first sub-chip 300A does not emit light, while the luminous brightness of the second sub-chip 300B is controlled by the second electrode 122.

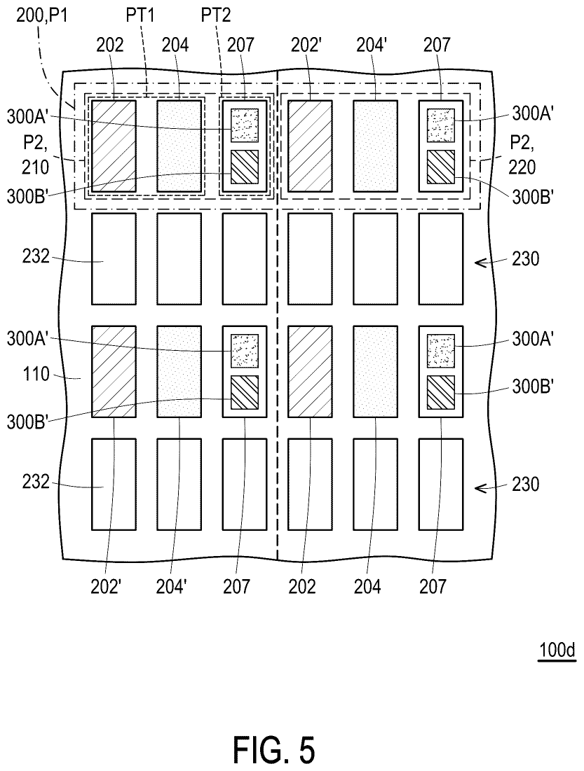

FIG. 5 is a partial top view of a display panel according to yet another embodiment of the present disclosure. Please refer to FIG. 5, a display panel 100d of this embodiment is similar to the display panel 100c of FIG. 4A, and the main differences between the two are as follows. In the display panel 100d of this embodiment, a first sub-chip 300A′ and a second sub-chip 300B′ included in a micro-light emitting chip 207 of the second part PT2 have different light emitting colors.

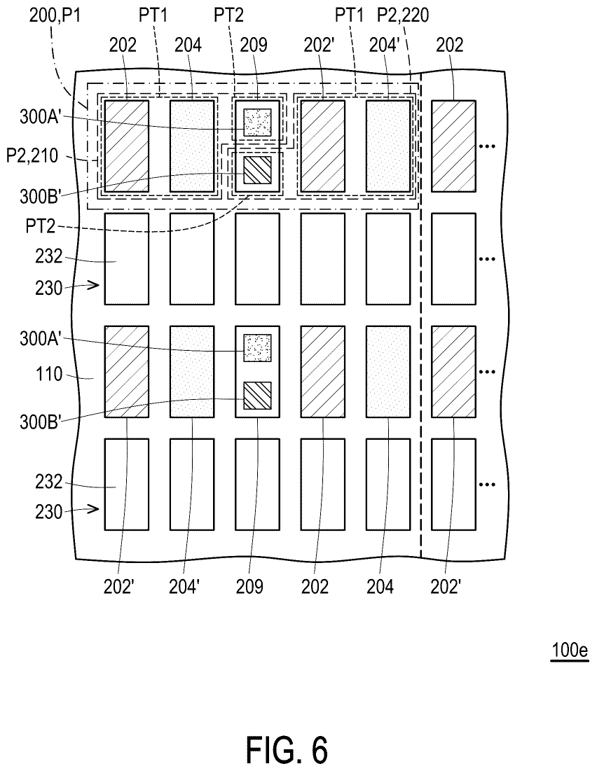

FIG. 6 is a partial top view of a display panel according to another embodiment of the present disclosure. Please refer to FIG. 6, a display panel 100e of this embodiment is similar to the display panel 100d of FIG. 5, and the main differences between the two are as follows. In the display panel 100e of this embodiment, the second parts PT2 of the subsets 210 and 220 are connected to each other to form an integrated chip 209. The integrated chip 209 includes two micro-light emitting chips (for example, the first sub-chip 300A′ and the second sub-chip 300B′ mentioned above), the conductive element 180A, and the intermediate electrode 123 described above. That is to say, the integrated chip 209 may be the micro-light emitting chip 207 described above. The two micro-light emitting chips (i.e., the first sub-chip 300A′ and the second sub-chip 300B′) of the integrated chip 209 have different light emitting colors. For example, the first sub-chip 300A′ emits blue light, while the second sub-chip 300B′ emits cyan light.

In summary, in the display panel of the embodiments of the present disclosure, since respective subsets include at least three micro-light emitting chips with different light emitting colors, and since the micro-light emitting chips included in the respective display units have at least four different light emitting colors, the at least three micro-light emitting chips with different light emitting colors may determine the color of the pixel, while the fourth micro-light emitting chip with another different light emitting color may be used to adjust the color coordinates of the vertex of the color gamut. Therefore, the display panel of the embodiments of the present disclosure may achieve the effect of adjustable color gamut.

What is claimed is:

1. A display panel, comprising:
a circuit substrate, defining a plurality of pixels; and
a plurality of display units, disposed on the circuit substrate to display the plurality of pixels, each of the plurality of display units comprising at least two adjacently arranged subsets, and each of the subsets comprising:
at least three micro-light emitting chips, and light emitting colors of the micro-light emitting chips being different from each other,
wherein the micro-light emitting chips comprised in each of the plurality of display units have at least four different light emitting colors.

2. The display panel as claimed in claim 1, wherein each of the plurality of display units correspondingly displays one of the plurality of pixels respectively, and each of the subsets of each of the plurality of display units is categorized into:
a first part, comprising the micro-light emitting chips having the same light emitting color and respectively disposed on each of the subsets; and
a second part, comprising the micro-light emitting chip disposed only on one of the subsets, and light emitting colors of the second parts of the subsets are different from each other.

3. The display panel as claimed in claim 2, wherein when the display unit displays the corresponding pixel, the second part of one of the subsets is turned off.

4. The display panel as claimed in claim 3, wherein a current density of the micro-light emitting chip of the second part of another of the subsets increases as the second part of one of the subsets is turned off.

5. The display panel as claimed in claim 2, wherein the micro-light emitting chips of all of the second parts are alternately disposed on the circuit substrate along with the plurality of display units.

6. The display panel as claimed in claim 2, wherein the micro-light emitting chip comprised in at least one of the second parts comprises:
two sub-chips, having a same light emitting color;
an insulating structure, disposed between the two sub-chips to make the two sub-chips electrically insulated from each other at the insulating structure;
a conductive element, electrically connecting the two sub-chips in series; and
a protection unit, the protection unit being an insulating layer, and the two sub-chips and the insulating structure being integrated within the protection unit.

7. The display panel as claimed in claim 6, wherein each of the two sub-chips has a central wavelength, and a difference between the two central wavelengths ranges from 2 nm to 20 nm.

8. The display panel as claimed in claim 2, wherein the second parts of the subsets are connected to each other to form an integrated chip, the integrated chip comprising:
two micro-light emitting chips, having different light emitting colors;
a conductive element, electrically connecting the two micro-light emitting chips in series; and
an intermediate electrode, connecting the conductive element and the circuit substrate.

9. The display panel as claimed in claim 2, wherein in at least one of the subsets, the micro-light emitting chips contained in the first part and having the same light emitting color respectively have a central wavelength, and a difference between any two of the central wavelengths ranges from 2 nm to 20 nm.

10. The display panel as claimed in claim 2, wherein in each of the plurality of display units, the micro-light emitting chip contained in the second part of one of the subsets has a light emitting color with coordinates (x, y) in a CIE 1931 chromaticity diagram located within a region enclosed by (0.0481, 0.2953), (0.0169, 0.7460), (0.0886, 0.6449), and (0.0989, 0.3018).

11. The display panel as claimed in claim 1, wherein each of the subsets respectively correspondingly displays one of the plurality of pixels, and each of the subsets of each of the plurality of display units is categorized into:
a first part, comprising the micro-light emitting chips having the same light emitting color and respectively disposed in each of the subsets; and
a second part, comprising the micro-light emitting chip disposed only in one of the subsets, and light emitting colors of the second parts of the subsets are different from each other.

12. The display panel as claimed in claim 11, wherein all of the micro-light emitting chips of the second parts are alternately disposed on the circuit substrate along with the subsets.

13. The display panel as claimed in claim 11, wherein the micro-light emitting chip comprised in at least one of the second parts comprises:
two sub-chips, having a same light emitting color;
an insulating structure, disposed between the two sub-chips such that the two sub-chips are electrically insulated from each other at the insulating structure;
a conductive element, electrically connecting the two sub-chips in series; and
a protection unit, the protection unit being an insulating layer, and the two sub-chips and the insulating structure being integrated within the protection unit.

14. The display panel as claimed in claim 13, wherein each of the two sub-chips has a central wavelength, and a difference between the two central wavelengths ranges from 2 nm to 20 nm.

15. The display panel as claimed in claim 1, further comprising:
a backup line, disposed on the circuit substrate and electrically connected to each of the subsets of each of the plurality of display units,
wherein within each of the plurality of display units, the backup line has a plurality of bonding regions corresponding to a number to the micro-light emitting chips of each of the subsets.

16. The display panel as claimed in claim 2, wherein the subsets of each of the plurality of display units define at least two color gamut ranges in a CIE 1931 chromaticity diagram according to the light emitting colors of the micro-light emitting chips, and each of the plurality of display units is controlled to select the color gamut range of one of the subsets to display the corresponding pixel.
